(19) United States
(12) Patent Application Publication
(10) Pub. No.: US 2006/0226860 A1
(43) Pub. Date: Oct. 12, 2006

(54) Compensation board for measurement using prober, program and recording media therefor

(75) Inventor: Yasushi Okawa, Tokyo (JP)

Correspondence Address: Paul D. Greeley;Ohlandt, Greeley, Ruggiero & Perle, L.L.P., 10th Floor, One Landmark Square, Stamford, CT, 06901-2682, US

(73) Assignee: Agilent Technologies, Inc.

(21) Appl. No.: 11/350,678

(22) Filed: Feb. 9, 2006

(30) Foreign Application Priority Data
Mar. 30, 2005 (JP) 2005-099378

(51) Int. Cl. G01R 31/26

(52) U.S. Cl. 324/719

(57) ABSTRACT

A compensation board having a pattern for load compensation, which comprises a resistor of 500Ω or higher and first and second pads for making contact with a probe needle, each of which are connected to a terminal of the resistor.

### FIELD OF THE INVENTION

The present invention relates to a compensation method for measuring the impedance of a device under test (DUT) by contacting the electrodes of the DUT with probe needles, probes, membrane probes, or other contact probes, and in particular, relates to measurement of the impedance of a DUT on a semiconductor wafer.

### DISCUSSION OF THE BACKGROUND ART

In the past, when mesurements were performed using high-frequency signals on a semiconductor wafer (a semiconductor wafer is simply referred to as a wafer hereinafter in the present Specification) using a wafer prober, it was necessary to apply compensation from the measurement device to the needle tip using a compensation board referred to as an impedance standard substrate (ISS). The substrate in Cascade Microtech, Inc. “Impedance Standard Substrates to support all of your high-frequency probing applications,⇄ [online], 2004, Catalog (Feb. 1, 2005 search), Internet “URL:http://ww.cmicro.com/pubs/ISSFAM-DS.PDF” is a known example of an ISS. This ISS is primarily used for compensation of measurement using RF signals, for example, measurement of S-parameters, and typically comprises a pad (electrode) group 404 for thru (THRU) compensation, a pad group 406 for short-circuit (SHORT) compensation, and a pad group 408 for load (LOAD) compensation. Each pad group is composed of a pattern that is appropriate for the respective measurement purpose, and the group is formed of multiple pads as a countermeasure to the wear that occurs as a result of probing using probe needles or other contact probes. The term contact probe in the present Specification means a tool that can probe a pad on the order of microns, and examples are probe needles, probes, and membrane probes.

A load compensation pattern 402 of the pad group for load compensation will be described in detail using FIG. 4 (B). Pattern 402 for load compensation is a compensation pattern referred to as an SG-type (signal-to-ground type), and is formed by a pad 412, which is probed on the S side (signal line side); a pad 416, which is probed on the G side (ground side); and a standard resistor 414, which is found between the two pads. Standard resistor 414 is 50Ω. The G-side pad 416 is longer than the S-side pad and is capable of responding to multiple pitches when both pads are probed. For instance, the pitch corresponds to 100 μm to 250 μm. During load compensation, a contact probe contacts the S-side pad 412 and the G-side pad 416, the resistance is measured, and the load is compensated. Furthermore, there is also an ISS wherein patterns 402 for load compensation are lined up in pairs as shown in FIG. 4(A) in such a way that it can even be used to compensate for measurement using RF signals with measurement systems that use four-point contact probes.

FIG. 4(C) shows a pattern 420 for load compensation that is different from the pattern shown in FIG. 4(B). This is called the GSG-type (ground-signal-ground-type). G-side pads 422 and 430 are set up at either end of an S-side pad 426 with respective standard resistors 424 and 428 in between. Standard resistors 424 and 428 each have a resistance of 100Ω such that the synthetic impedance becomes 50Ω. An SG, GSG, or other type of pattern is used for connection methods from a cable, but the value of the respective standard resistor for load compensation is set such that the synthetic impedance is 50Ω in order to keep impedance matching for measurement in the RF region.

However, in recent years attention has been focused on techniques for measuring the capacitance of the insulation film during the semiconductor production process, particularly techniquies for measuring capacitance-voltage characteristics. Examples of insulation films in the semiconductor insulation process are MIS (Metal Insulator Silicon)-CAP (CAPacitor) that has been made from the insulation film of a transistor, MOS (Metal Oxide Silicon)-CAP, which has been made from the insulation film of a transistor, MIS-FET gate insulation film, MOS-FET gate insulation film, and MOS capacitor gate insulation film. It should be noted that gate insulation films include gate oxide films.

As cited in Agilent Technologies, Product note: “Agilent Technologies C-V: Property evaluation of gate oxide film of MOS capacitor by Agilent Technologies 4294A,” [online], Jun. 25, 2003, Product Notes [Feb. 1, 2005 search], Internet “URL:http://www.home.agilent.com/cgibin/pub/agilent/reuse/cp_ObservationLogRedirector.jsp?NAV_ID=111 44.0.00&LANGUAGE_CODE=jpn&CONTENT_KEY=1000002192%3aepsg %3aapn&COUNTRY_CODE=JP&CONTENT_TYPE=AGILENT_EDITORIAL,” pp, 6 and 7, when an insulation film is measured, the capacitance is measured using an impedance measurement device, such as an impedance analyzer (for instance, Agilent 4284A, Agilent 4285A, or Agilent 4294A made by Agilent Technologies). When an insulation film on a wafer is measured in this case using high-frequency signals of 1 MHz or higher, it is necessary to apply OPEN/SHORT/LOAD compensation at the tip of the contact probe using a compensation substrate (ISS) in order to reduce the error that is generated by a measurement system that comprises contact probes such as probe needles and cables connected from the measurement device to contact probes.

OPEN/SHORT/LOAD compensation using an ISS is conducted as follows. When measuring the impedance in an open-circuit state, the impedance is measured by an impedance measurement device without touch down of the contact probes on the ISS, that is, without any contact from the contact probes. When the impedance is measured in a short-circuit state, the impedance is measured by bringing the contact probes into contact with the short-circuit pattern of the ISS. When measuring under a load, the impedance is measured by bringing the contact probes into contact with the pads of the load pattern of the ISS. Measurement compensation is performed according to the formula shown in FIG. 5-2(B) of the above-mentioned Agilent Technologies Product note “Agilent Technologies C-V: Property evaluation of gate oxide film of MOS capacitor by Agilent Technologies 4294A” using these measurements.

However, degradation and contamination of the tips of the contact probes and degradation of the pad surface (touch down imprint or oxidation) increase contact resistance and this increase is included in the measurement of compensation. Therefore, when there is an increase in the contact resistance for measurements from short-circuit compensation or measurements from load compensation, this can have a strong impact on compensation of the measurements. In such cases the measurement results are not correctly compensated. Therefore, if the operator suspects that there has been an increase in contact resistance because the results of measuring a DUT are suspicious, he will attempt to correct the problem by cleaning or polishing the tips of the contact probes, cleaning the ISS pads, micro-adjusting the position of contact of the contact probes with the pads, changing the pads used with the ISS to new pads that still do not have touch down imprints, and the like. In such a case, there is a problem in that it takes a long time to restart the measurement, regardless of which solution has been implemented. Moreover, there is a problem in that if the increase in contact resistance is not noticed from the measurement results, the measurement results that are obtained will be included considerable errors caused by the incorrect compensation.

In light of the problems with the above-mentioned prior art, the inventors focused on the fact that there are times when the contact resistance between a contact probe and a pad can be as high as 10Ω and in such cases, an error of as much as 20% is included in measurements under a load of 50Ω; therefore, the measurements for compensation also include an error as large as 20% because of this increased contact resistance and this has a large impact on compensation of measurements.

The inventors further focused on the point that compensation using 50Ω as the load impedance is not always necessary with an impedance measurement device, which is a measurement device used to measure the capacitance of an insulation film during the semiconductor production process, and compensation can be accomplished with any impedance. In particular, impedance is usually 1 kΩ or higher when an MOS capacitor or other insulation film is the DUT; therefore, it is preferred that, rather than 50Ω, a value close to the impedance of the DUT be used as the impedance for load compensation of an impedance measurement device because the error can be reduced thereby.

Moreover, the inventors also focused on the fact that the conventional compensation boards were developed for RF applications; therefore, taking impedance matching into consideration, a relatively low resistance of 50 or 100Ω is the most commonly used load resistance.

Taking the above-mentioned points into consideration, an object of the present invention is to provide a compensation board suitable for load compensation in relation to measurement with an impedance analyzer using a probe needle, or other contact probe; a measurement program for this board; and a recording medium for this program.

Another object of the present invention is to provide a compensation board for the above-mentioned measurement with which it is possible to reduce the number of times load compensation is repeated because of an increase in the contact resistance in load compensation; a measurement program for this board; and a recording medium for this program.

Yet another object of the present invention is to provide a compensation board for the above-mentioned measurement with which it is possible to perform load compensation at an impedance close to that of the DUT and reduce the measurement error; a measurement program for this board; and a recording medium for this program.

### SUMMARY OF THE INVENTION

The compensation board of the present invention is characterized in that it has a pattern for load compensation comprising a resistor of 500Ω or higher and first and second pads with which the contact probe makes contact, which are connected to each terminal of the above-mentioned resistor. The present subject also includes the case where there are multiple patterns for load compensation; the case where the above-mentioned resistor is 1 kΩ; and the case where there is also a pattern for short-circuit compensation. In addition, the present subject includes the case where the contact probe is a probe needle, and the case where the compensation board is a compensation board used for compensation of measurements of insulation film capacitance during the semiconductor production process.

The impedance standard substrate of the present invention is characterized in that an impedance standard substrate for compensation by contact with contact probes comprises the standard resistor for a load compensation of 500Ω or higher. This subject also includes the case where this impedance standard substrate is a substrate that is used for compensation of measurements of insulation film capacitance during the semiconductor production process.

The computer program that performs compensation of the present invention is characterized in that, by means of a measurement system comprising a compensation board of either the above-mentioned first subject or the subordinate subjects; a measurement device for measuring impedance that is connected to the first and second pads of the compensation board via a first and second contact probe, respectively; and a controller for controlling the measurement device such as a computer with a CPU and a memory, the controller sends to the measurement device commands for measuring the impedance of the open-circuit compensation; commands for measuring the impedance of the short-circuit compensation, and commands for measuring the impedance of load compensation at a resistance of 500Ω or higher. Moreover, this subject also includes the case where the controller executes a command to the measurement device for inputting a predetermined impedance of the compensation board of a resistance of 500Ω or higher.

The computer-readable recording medium of the present invention is characterized in that the computer program of the above-mentioned third subject or the subordinate subjects is recorded on this medium.

As described above, when the present invention is used, the load compensation, that was performed with a resistance as low as 50Ω in the past for the above-mentioned measurement, can be conducted using a resistance of 500Ω or higher; therefore, it is possible to provide a compensation board appropriate for load compensation with which there is virtually no wearing of the contact probes or pads; a measurement program for this board; and a recording medium for this program.

In addition, when the present invention is used, it is possible to perform the load compensation that was performed in the past with a resistance as low as 50 or 100Ω for the above-mentioned measurement can be conducted using a resistance of 500Ω or higher; therefore, it is possible to provide a compensation board effective for reducing retries of the load compensation caused by increased contact resistance due to degradation and contamination of the contact probes or pads and reducing the error ratio affected by the increased contact resistance accounted in the measurement value; a measurement program for this board; and a recording medium for this program.

Furthermore, when the present invention is used, the load compensation relating to the above-mentioned measurement that previously was conducted at a resistance as low as 50 ohms can be conducted close to the impedance of the device under test in the above-mentioned test; therefore, test errors can be reduced because load compensation can be conducted at an impedance close to that of the device under test.

### BRIEF DESCRIPTION OF THE DRAWINGS

FIG. 1(A) is an outline of the ISS of the present invention, FIG. 1(B) shows the details of the load compensation pattern 102 of FIG. 1(A), and FIG. 1(C) shows the details of a load compensation pattern that is a different embodiment from FIG. 1(B).

FIG. 2 is an outline of a measurement system that measures load compensation using the ISS of the present invention.

FIG. 3 is a flow chart of the measurement program that is executed by the measurement system shown in FIG. 2.

FIG. 4(A) is an outline of a conventional ISS, FIG. 4(B) shows the details of the SG-type load compensation pattern 402 of FIG. 4(A), and FIG. 4(C) shows the details of the GSG-type load compensation pattern.

FIG. 5 is a model for introducing the compensation formula for compensation by the present invention.

### DETAILED DESCRIPTION OF THE PREFERRED EMBODIMENT

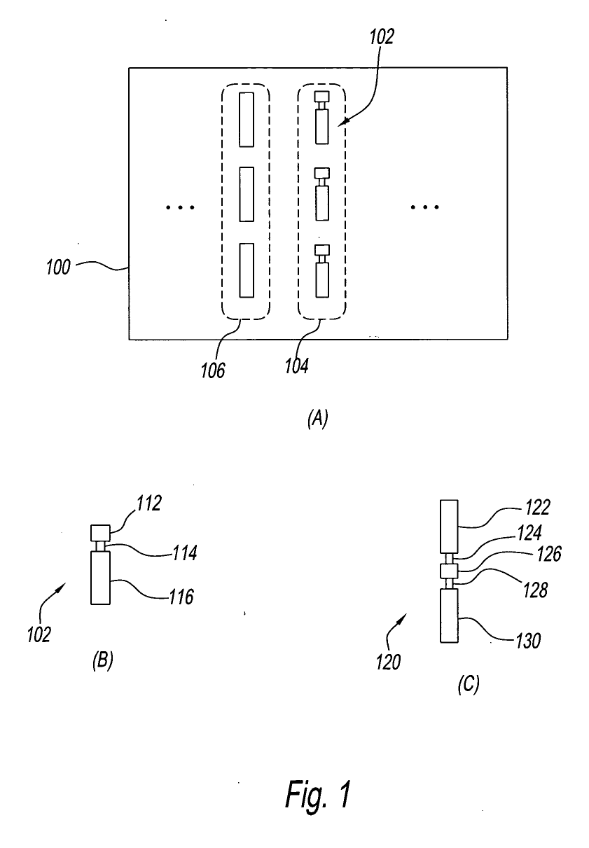

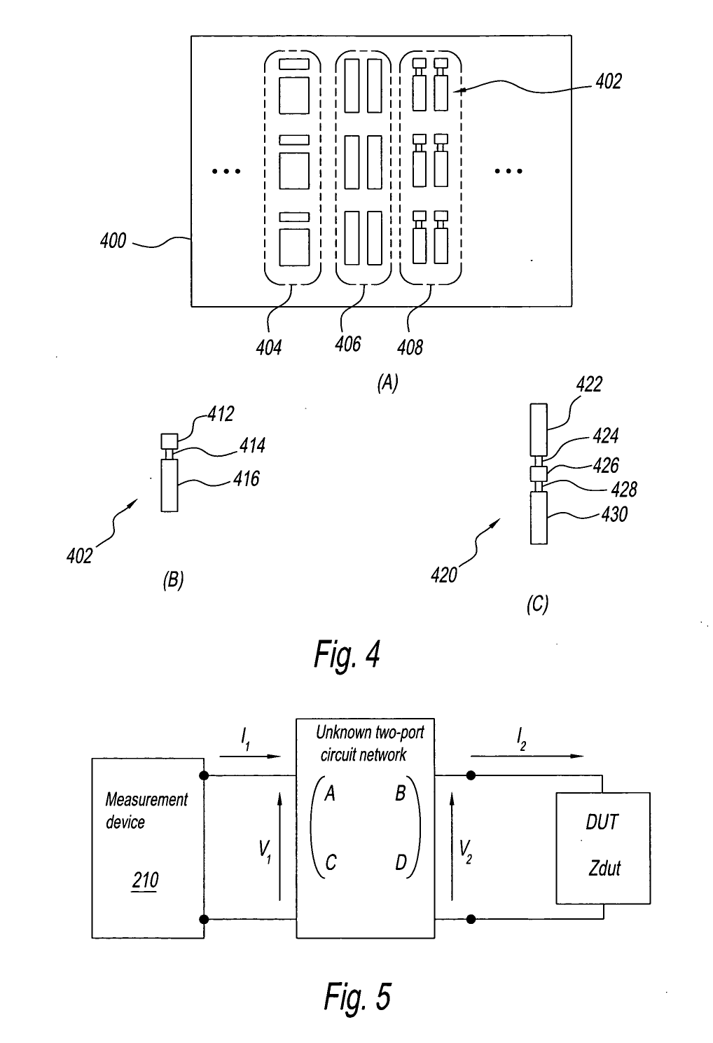

An ISS (100) of the present invention will be described while referring to FIG. 1 (A). ISS (100) of the present invention comprises a pad group 104 of multiple load resistors and a pad group 106 for short-circuit compensation comprising multiple short-circuit patterns. This short-circuit compensation pattern is the same as the short-circuit compensation pattern of the ISS of the prior art shown in FIG. 4. One of the patterns, pattern 102, for load compensation of pad group 104 of load resistance, is shown in detail in FIG. 1(B). Pattern 102 for load compensation is shown as an SG (signal-ground) pattern. Pattern 102 is formed from a pad 112, which is probed on the S-side; a pad 116, which is probed on the G side; and a standard resistor 114, which is found in between these pads. Standard resistor 114 is resistor of 500Ω or higher and is, for instance, 500Ω or 1Ω. The G-side pad 116 is longer than the S-side pad and can respond to multiple pitches when both pads are probed. For instance, it responds to a pitch of 100 μm to 250 μm. When load compensation is performed, the contact probes contact S-side pad 112 and G-side pad 116 and the resistance is measured and compensated.

Moreover, FIG. 1(C) shows a pattern 120 for GSG-type load compensation. G-side pads 122 and 130 are disposed on either side of an S-side pad 126 with respective standard resistors 124 and 128 in between. The resistance of standard resistors 124 and 128 is set such that the synthetic impedance is 500Ω or higher. For instance, when the synthetic impedance is 500Ω, the resistance of both standard resistors 124 and 128 is 1 kβ. Moreover, when the synthetic impedance is 1 kΩ, the resistance of both standard resistors 124 and 128 is 2 kβ. By similarly determining the resistance, a pattern that uses a standard resistor of 500β or higher can be used for the pattern for load compensation of a type other than SG or GSG.

The error during compensation when the state of the contact probes and pads is inadequate will now be considered. The impedance Zdut of a DUT is calculated by the following formula from the circuit model shown in FIG. 5.
Zdut=Zstd(Zo−Zsm)(Zxm−Zs)/((Zsm−Zs)(Zo−Zxm)) (1)

Here,

Zo is the measurement value of impedance when the circuit between the terminals is open,

Zs is the measurement value of impedance when the circuit between the terminals is shorted (does not include contact resistance),

Zstd is the known load impedance,

Zsm is the measurement value of impedance when the known load impedance is connected between terminals (does not include contact resistance),

Zxm is the measurement value of impedance of a device under test (DUT), and

Zdut is the impedance of the DUT after compensation.

However, the contact resistance is not included in Zs or Zsm in formula (1); therefore, the effect of the contact resistance on Zdut is not considered. Consequently, the measurement valus of impendance Zs′ and Zsm′ which includes the contact resistance on Zs and Zsm, respectively, are represented by the following formula, where the contact resistance during short-circuit compensation measurement is Rcs and the contact resistance during load compensation measurement is Rc1:
Zs′=Zs+Rcs
Zsm′=Zsm+Rc1
The impedance of a DUT that includes contact resistance, Zdut′, will be considered wherein Zs and Zsm in formula (1) have been replaced by Zs′ and Zsm′. It should be noted that here, Zs≈0 and Zsm≈Zstd.

The error, which shows the ratio of the error between Zdut and Zdut′, is calculated by the following formula:

$$\begin{matrix}Error = 1 - ( {Zdut}^{′} / Zdut ) \\ \approx 1 - \{ ( Zxm - Zs - Rcs ) / ( Zxm - Zs ) \} \{ ( Zsm - Zs ) / \\ ( Zsm + Rc 1 - Zs - Rcs ) \} \\ \approx 1 - \{ ( Zxm - Zs - Rcs ) / ( Zxm - Zs ) \} \{ ( Zstd - Zs ) / \\ ( Zstd + Rc 1 - Zs - Rcs ) \}\end{matrix}$$

Where Zo>>Zsm.

When Rc1=10Ω and Rcs=0Ω as the worst case scenario, the error, or the ratio of error, is 2% when Zstd=500Ω; Zs=0Ω, and the impedance of the DUT is 10 kΩ, while the error with conventional Zstd=50Ω is 20%. Moreover, by taking the above-mentioned conditions into consideration when Rc=5Ω, the error is 1% with a Zstd=500Ω, while the error is 10% when Zstd=50Ω.

As described above, it is possible to perform load compensation of an impedance measurement device with any impedance other than 50Ω under standard resistance for load compensation of an ISS when measuring impedance in a high-frequency region of 1 MHz or higher. In addition, the impedance of the DUT is 1 kΩ or higher; therefore, the error can be disregarded, even if the contact resistance between a contact probe and pad has increased, by using the pattern for load compensation that uses a standard resistance of 500Ω or higher, for instance, 1 kΩ. Consequently, it is not necessary to repeat the measurement for load compensation.

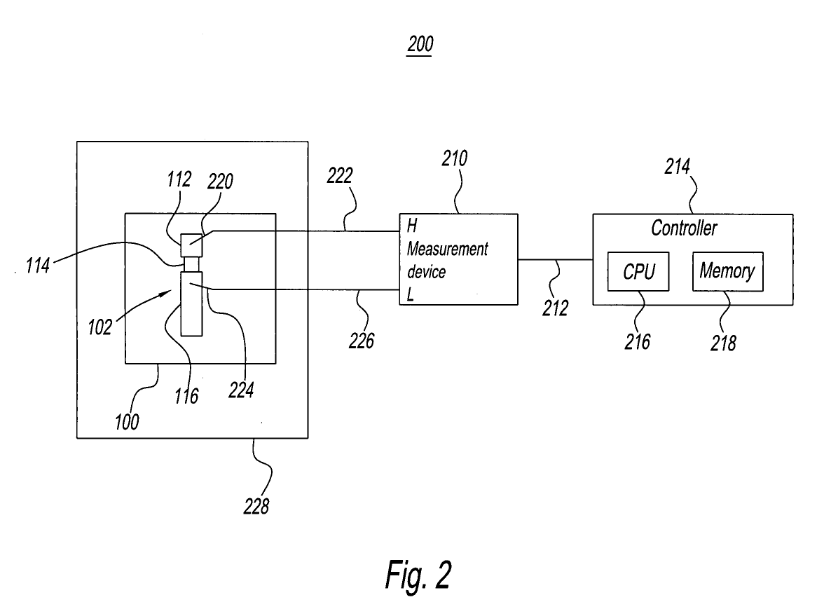

A measuring system 200 for compensation using, for instance, pattern 102 for load compensation in FIG. 1(B), will be described as a measuring system for compensation using the ISS of the present invention by means of FIG. 2. Pattern 102 for load compensation that was described in FIG. 1(B) is used for the ISS (100), and the S-side pad 112 of pattern 102 is probed by a contact probe 220 via a cable 222 from the H-side terminal of a measurement device 210 for measuring the impedance, while the G-side pad 116 of pattern 102 is probed by a contact probe 224 via a cable 226 from the L-side terminal of measurement device 210. Measurement device 210 is connected to a controller 214 by GP-IB, or another control bus 212. Controller 214 is preferably a PC or other computer and houses a CPU, or a processor, 216 as the operating means and a memory 218 for storing programs and data. It should be noted that ISS (100) and contact probes 220 and 224 are preferably inside a prober 228 for high-precision, simple alignment. Moreover, prober 228 can be manually operated and aligned by an operator instead of being controlled from controller 214. Prober 228 can also be connected to controller 214 and controlled from controller 214.

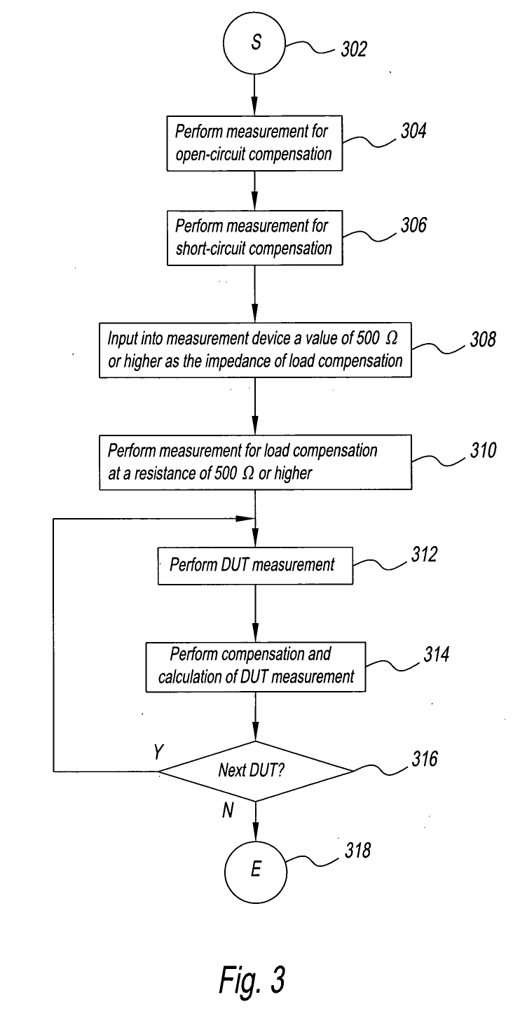

Next, a flow chart for the measurement program for compensation that is executed by measurement system 200 in FIG. 2 will be described using FIG. 3. Measurement system 200 first performs each step 304, 306, 308, and 310 in FIG. 3 as measurement steps for compensation using an ISS or other compensation board by controller 214 before measuring the DUT by impedance measurement device 210 via contact probes 220 and 224. That is, the program starts at step 302, and the impedance for open-circuit compensation is measured at step 304 without allowing the contact probes to touch down on the compensation board. Then the contact probes are brought into contact with the short-circuit pattern of the compensation board in step 306 and the impedance for short-circuit compensation is measured. Next, a value of 500Ω or higher is input to the measurement device as the impedance of load compensation that will be performed in step 308. A measurement that was separately obtained with high precision, or any value, is input as the value of resistance for load compensation of the compensation board. Next, in step 310, measurement for load compensation is performed using a resistance of 500Ω or greater.

Measurement system 200 actually measures a DUT and applies compensation as described below using the resulting compensation data. First, in step 312, the contact probes are brought into contact with the device under test (DUT) and the impedance is measured by measurement device 210. Then the measurements for the DUT are compensated and calculated using above-mentioned formula (1) and the resulting impedance measurement for the DUT and compensation data. The system evaluates whether there will be another DUT measurement in step 316 and if the system continues measuring, it proceeds to step 312, but if it does not continue measuring, it proceeds to step 318 and the probes are turned off. Thus, the value of the resistance for load compensation of the compensation board has been brought to 500Ω or higher and therefore, it is possible to continue with measurement for compensation and measurement of a DUT without taking note of the value of the contact resistance of the contact probes and pads of the pattern for load compensation. Therefore, the operator can save the time that is normally used to repeat compensation and measurement.

The order of steps 304, 306, 308, and 310 in FIG. 3 can be switched without causing any problems in terms of compensation, and the program can be changed so that step 308 is performed after step 310. Moreover, step 314 is not necessarily conducted immediately after step 312, and changes can be made so that steps 304, 306, 308, and 310 are performed and step 314 is conducted on a series of measurement results once the series of measurements of the DUT have been completed.

There is also an embodiment wherein in step 310 and/or step 306 in FIG. 3, the system brings the contact probes into contact with the target pattern for compensation and evaluates whether or not the contact resistance is anomalous. If it is not anomalous, the system measures for precise compensation of the targeted compensation pattern, but if the contact resistance value is anomalous, this anomaly is displayed and the program is ended. The pre-measurement of impedance in this case means that the impedance is roughly measured in a short time. For instance, the impedance is measured at a low frequency of 1 kHz to 10 kHz. It is possible to quickly estimate the impedance of the contact resistance minus the effect of the residual inductance or parasitic capacitance of the measurement system by pre-measuring the impedance at such a low frequency. Moreover, the difference from zero Ω can be used for short-circuit compensation and the value of the resistance for load compensation that has been separately pre-assigned a value can be used for load compensation when calculating the contact resistance for the pre-measurement of impedance.

The present invention was described based on the embodiments given here, but various modifications and changes can be made based on the concept of the present invention. For instance, the load compensation pattern 102 in FIG. 1 can be formed by lining up in pairs as with the load compensation pattern 402 in FIG. 4 and used with a measurement system having four-point contact probes.

What is claimed is:

1. A compensation board having a pattern for load compensation, said compensation board comprising a resistor of 500Ω or higher and first and second pads for contact by contact probes, each of which is connected to a terminal of the resistor.

2. The compensation board according to claim 1, further comprising multiple patterns for load compensation.

3. The compensation board according to claim 1, wherein said resistor is 1 kΩ.

4. The compensation board according to claim 1, wherein said pattern is for short circuit compensation.

5. The compensation board according to claim 1, wherein said contact probes are probe needles.

6. The compensation board according to claim 1, wherein said compensation board is used for compensation of measurement of insulation film capacitance during the semiconductor production process.

7. An impedance standard substrate for compensation by making contact with a contact probe, wherein said substrate comprises a standard resistor of 500Ω or higher for load compensation.

8. The impedance standard substrate according to claim 7, wherein said impedance standard substrate is used for compensation of measurement of insulation film capacitance during the semiconductor production process.

9. A computer program, characterized in that by means of a measurement system comprising a compensation board comprising a resistor of 500Ω or higher and first and second pads for contact by contact probes, each of which is connected to a terminal of the resistor, a measurement device for measuring the impedance that is associated with the first and second pads of the compensation board via first and second contact probes, respectively, and a controller with a CPU for controlling the measurement device, wherein the controller executes the following:
a command to the measurement device for measuring open-circuit compensation impedance;
a command to the measurement device for measuring short-circuit compensation impedance; and
a command to the measurement device for measuring the load compensation impedance at a resistance of 500Ω or higher.

10. The computer program according to claim 9, wherein said controller executes a command to the measurement device for inputting a pre-determined impedance of the compensation board at a resistance of 500Ω or higher.

11. A computer-readable recording medium capable of executing a computer program, characterized in that by means of a measurement system comprising a compensation board comprising a resistor of 500Ω or higher and first and second pads for contact by contact probes, each of which is connected to a terminal of the resistor, a measurement device for measuring the impedance that is associated with the first and second pads of the compensation board via first and second contact probes, respectively, and a controller with a CPU for controlling the measurement device, wherein the controller executes the following:
a command to the measurement device for measuring open-circuit compensation impedance;
a command to the measurement device for measuring short-circuit compensation impedance; and
a command to the measurement device for measuring the load compensation impedance at a resistance of 500Ω or higher.

12. A computer-readable recording medium according to claim 11, wherein said controller executes a command to the measurement device for inputting a pre-determined impedance of the compensation board at a resistance of 500Ω or higher.
